(19) United States
(12) Patent Application Publication
(10) Pub. No.: US 2025/0293004 A1
(43) Pub. Date: Sep. 18, 2025

(54) SEMICONDUCTOR PROCESSING CHAMBER LID AND SEALING MECHANISM

(71) Applicant: Applied Materials, Inc., Santa Clara, CA (US)

(72) Inventors: Santosh S. Nesarkar, Bangalore (IN); Srikantha Mallappa, Karnataka (IN); Imad Yousif, San Jose, CA (US)

(21) Appl. No.: 18/603,672

(22) Filed: Mar. 13, 2024

(51) Int. Cl. H01J 37/32; H01L 21/67

(52) U.S. Cl. CPC H01J 37/32513; H01J 37/32082; H01J 37/3244; H01J 2237/334; H01L 21/67069

(57) ABSTRACT

Semiconductor processing systems and system components are described. A spring-loaded sealing mechanism for a chamber lid of a semiconductor processing chamber includes a compression plate affixed to a source assembly of the processing chamber, and a set of springs including first ends of each of the springs affixed to a first surface of the compression plate, respective lengths of each of the springs oriented orthogonally with respect to a plane of the compression plate, and second ends of each of the springs contacting a fixture of the source assembly. The compression plate is arranged with respect to the source assembly such that, when the source assembly is in a closed position, the compression plate applies a compressive force on a gas hub of the chamber lid to compress a dimension of at least one seal between the gas hub and the chamber lid by at least 15%.

### BACKGROUND

This specification relates to semiconductor systems, processes, and equipment.

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched. As scaling of integrated circuits continues to move towards smaller features and increased aspect ratios, there is a growing need for precision etching of layer structures.

### SUMMARY

This specification describes technologies for a spring-loaded clamping and sealing mechanism for a plasma-based processing chamber.

One type of plasma source is an inductively coupled plasma. In some plasma-based processing chambers, the plasma source is located above a lid of the chamber. During processing, an etching gas mixture flows through the gas delivery nozzle to form a plasma in a processing region of the chamber. Charged particles of the plasma are drawn towards an exposed surface of a substrate retained in the processing region of the chamber to perform an etching process on the exposed surface. Compositions of etching gas mixtures can be selected to etch different layer compositions, for example, a first etching gas mixture to etch silicon oxide (SiO) and a second etching gas mixture to etch silicon nitride (SiN). A semiconductor processing chamber can include one or more (e.g., two or more) processing regions, each with a respective substrate holder to retain a respective substrate and individually controllable etching gas mixtures to form a respective plasma in the processing regions.

In inductively coupled plasma base fabrication systems, the lid is composed of a dielectric material to provide a dielectric window allowing the transfer of energy into the chamber. Inductively coupled plasma generate a large amount of heat. As such, chamber lid geometries are highly susceptible to non-uniformities generated by proximity of the plasma to the chamber lid. Non-uniform heating of the chamber lid can compromise the structural integrity of the chamber lid through induced stressed which can lead to cracking and/or loss of vacuum integrity during operation of the plasma-based processing chamber.

In general, one innovative aspect of the subject matter described in this specification can be embodied in a system for semiconductor processing. The system includes a chamber body including walls for enclosing a processing region, first substrate support within the chamber body and configured to retain a substrate in the processing region of the chamber body, a chamber lid arranged with respect to the walls of the chamber body to enclose the processing region. The chamber lid includes a lid portion including an aperture from a first surface of the lid portion to a second surface of the lid portion, a gas distribution nozzle disposed within the aperture of the lid portion, and a gas hub arranged on the first surface of the lid portion. At least one seal is arranged between a first end of the gas hub and the first surface of the lid portion. The system includes a source assembly including a plasma source configured to direct RF energy into the chamber body, an adjustable support frame configurable to position the source assembly from a first, open position to a second, closed position with respect to the chamber lid, a plate affixed to the source assembly, and a set of springs affixed to a first surface of the plate and oriented orthogonally with respect to a plane of the plate. The plate is arranged with respect to the source assembly to contact a second end of the gas hub with a second surface of the plate when the source assembly is in a second, closed position, such that the set of springs apply a compressive force to compress the at least one seal located between the first end of the gas hub and the first surface of the lid portion.

In general, another innovative aspect of the subject matter described in this specification can be embodied in methods for spring-loaded sealing of a semiconductor processing chamber including contacting a first end of a gas hub with a first surface of a compression plate, where a second end of the gas hub is arranged on a first surface of a lid portion of a chamber lid arranged on a chamber body of the semiconductor processing chamber, where at least one seal is arranged between the second end of the gas hub and the first surface of the lid portion. The methods include applying, by a set of springs arranged on a second surface of the compression plate, a compression force on the first end of the gas hub by the compression plate, the compression force compressing the at least one seal between the second end of the gas hub and the first surface of the lid portion.

In general, another innovative aspect of the subject matter described in this specification can be embodied in a spring-loaded sealing mechanism for a chamber lid of a semiconductor processing chamber including a compression plate affixed to a source assembly of the processing chamber, and a set of springs including first ends of each of the set of springs affixed to a first surface of the compression plate, respective lengths of each of the set of springs oriented orthogonally with respect to a plane of the compression plate, and second ends of each of the set of springs contacting a fixture of the source assembly. The compression plate is arranged with respect to the source assembly such that, when the source assembly is in a closed position, the compression plate applies a compressive force on a gas hub of the chamber lid to compress a dimension of at least one seal between the gas hub and the chamber lid by at least 15%.

The subject matter described in this specification can be implemented in these and other embodiments so as to realize one or more of the following advantages. As described herein, a chamber lid design that reduces a stress profile of the chamber lid can include minimizing structural features that could otherwise serve as failure points due to non-uniform heating. Reducing/removing these weak points in the structural features can improve the reliability of the chamber lid to maintain structural and vacuum integrity of the chamber lid as a component of the plasma-based vacuum chamber. Moreover, by reducing/removing the structural features and implementing a more uniform, flat lid design, a thermal uniformity over the lid surface can be improved.

Additionally, the spring-loaded clamping and vacuum sealing mechanism provides a solution for auto-sealing between the gas hub and the gas nozzle by a spring-loaded clamping to compress the seals located between the gas hub and the gas nozzle. The spring-loaded clamping and vacuum sealing mechanism can be implemented without requiring an operator to manually tightening/loosening of the sealing mechanism, which can reduce human error and/or reduce a burden on the human operator to perform the additional task.

Although the remaining disclosure will identify specific etching processes using the disclosed technology, it will be readily understood that the systems and methods are equally applicable to a variety of other processes as can occur in the described chambers. Accordingly, the technology should not be considered to be so limited as for use with the described etching processes alone. The disclosure will discuss one possible system and chamber that can be used with the present technology before describing systems and methods or operations of exemplary process sequences according to some embodiments of the present technology. It is to be understood that the technology is not limited to the equipment described, and processes discussed can be performed in any number of processing chambers and systems.

### BRIEF DESCRIPTION OF THE DRAWINGS

FIG. 1 shows a schematic cross-sectional view of an example processing chamber.

FIG. 2 shows a schematic cross-sectional partial view of an example plasma processing chamber.

FIG. 3 shows a schematic cross-sectional partial view of an example plasma processing chamber.

FIGS. 4A and 4B show schematic cross-sectional partial views of an example plasma processing chamber.

FIGS. 5A and 5B show schematic cross-sectional partial views of an example plasma processing chamber.

FIG. 6 is a flow diagram of an example of a process of a semiconductor processing chamber.

Like reference numbers and designations in the various drawings indicate like elements.

### DETAILED DESCRIPTION

The present specification describes technologies for a spring-loaded clamping and sealing mechanism for a plasma processing chamber. A spring-loaded clamping mechanism engages when a spring-loaded compression plate affixed to a moveable source assembly is positioned to contact a corresponding portion of a lid assembly of the plasma processing chamber. The spring force between the compression plate and the portion of the lid assembly creates a seal by applying a force to compress and deform compression-based seals of the lid assembly.

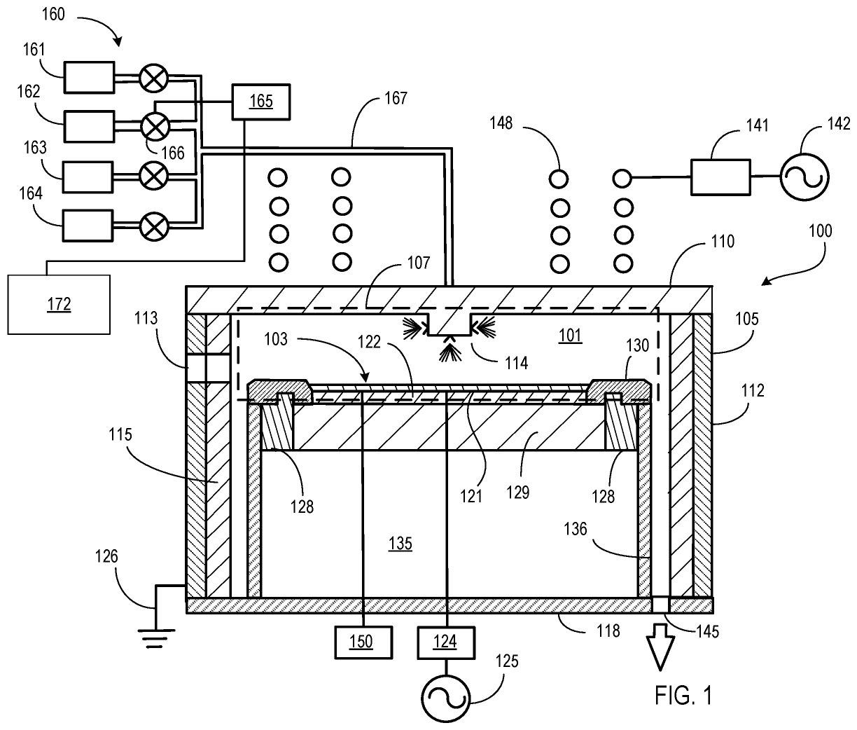

FIG. 1 illustrates a schematic cross-sectional view of an example processing chamber 100 suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid 110 to enclose the chamber volume 101. The chamber body 105 can be fabricated from, for example, aluminum or other suitable materials. A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more pumps and throttle valves.

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing. The electrostatic chuck (“ESC”) 122 can use the electrostatic attraction to hold the substrate 103 to the substrate support 135. The ESC 122 can be powered by a radio frequency (“RF”) power supply 125 integrated with a match circuit 124. The ESC 122 can include an electrode 121 embedded within a dielectric body. The electrode 121 can be coupled with the RF power supply 125 and can provide a bias which attracts plasma ions, formed from the process gases in the chamber volume 101, to the ESC 122 and substrate 103 seated on the pedestal. The RF power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma gases and to extend the time between maintenance of the plasma processing chamber 100.

Electrode 121 can be coupled with a DC power source 150. The power source 150 can provide a chucking voltage of about 200 volts to about 2000 volts to the electrode 121. The power source 150 can also include a system controller for controlling the operation of the electrode 121 by directing a DC current to the electrode 121 for chucking and de-chucking the substrate 103. The ESC 122 can include heaters disposed within the ESC 122 and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about −150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

A gas panel 160 (e.g., also referred to herein as “gas distribution manifold”) can be coupled by a gas line 167 with the chamber body 105 through chamber lid 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves, pressure regulators (not shown), and mass flow controllers (not shown) arranged with respect to the gas sources 161, 162, 163, 164 to control the flow of the process gases from the sources. Valves 166 can control the flow of the process gases from the sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers. The lid 110 includes include an aperture where the aperture accommodates a gas delivery nozzle 114, also referred to herein as a “gas nozzle.” The gas delivery nozzle 114 can include one or more openings for introducing the process gases from the sources 161, 162, 163, 164 of the gas panel 160 into the chamber volume 101. After the process gases are introduced into the plasma processing chamber 100, the gases can be energized to form a plasma. An antenna 148, such as one or more inductor coils, can be provided adjacent to the plasma processing chamber 100. An antenna power supply 142 can power the antenna 148 through a match circuit 141 to inductively couple energy, such as RF energy, to the process gas to maintain a plasma formed from the process gas in the chamber volume 101 of the plasma processing chamber 100. The operation of the power supply 142 can be controlled by a controller, such as controller 165, that also controls the operation of other components in the plasma processing chamber 100.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some embodiments, controller 165 is in data communication with a characterization device 172. Characterization device 172 can include one or more sensors (e.g., image sensors) operable to collect processing data related to processing chamber 100. For example, characterization device 172 includes an optical emission spectroscopy device configured to monitor a signal, e.g., emitted light of a plasma, within a processing region of the processing chamber 100. For example, a signal can be a primary or highest intensity wavelength of emitted light. Characteristics of the emitted light (e.g., wavelength and intensity) from the plasma within the processing region can depend in part on an etching gas mixture used to generate the plasma as well as a layer composition of the layer being etched. For example, each etching gas mixture and corresponding layer composition being etched can have a respective signal signature. Emitted wavelengths that are unique or distinguishing for each etching gas mixture and corresponding layer composition can be monitored to determine an etching condition of the layer being etched. For example, a thickness remaining of the layer being etched. Characteristics of the emitted light from the plasma can change, e.g., based on the etching process. For example, an intensity of a monitored signal can change as material is removed from the layer being processed. Characterization device 172 can be configured to collect processing data including the respective signals corresponding to the etching gas mixtures utilized in the wafer processing and corresponding layer compositions of the structure being processed in the processing chamber 100. Controller 165 can receive processing data from the characterization device 172 and determine, from the processing data, one or more actions to perform.

In some embodiments, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

Although described with respect to FIG. 1 as a process chamber including a substrate support disposed within a processing region of the chamber volume, two or more substrate supports can be disposed within the same chamber volume in respective processing regions, e.g., in respective processing stations. For example, a processing chamber 100 can be a tandem processing chamber including two processing regions each with respective substrate supports configured to retain respective wafers during etching process(es). The processing chamber 100 can include two or more processing regions within the chamber volume 101 to facilitate parallel processing of two or more substrates in respective processing regions. The processing regions can be substantially isolated such that an etching process in a first processing region has minimal effect on an etching process in a second processing region and vice-versa.

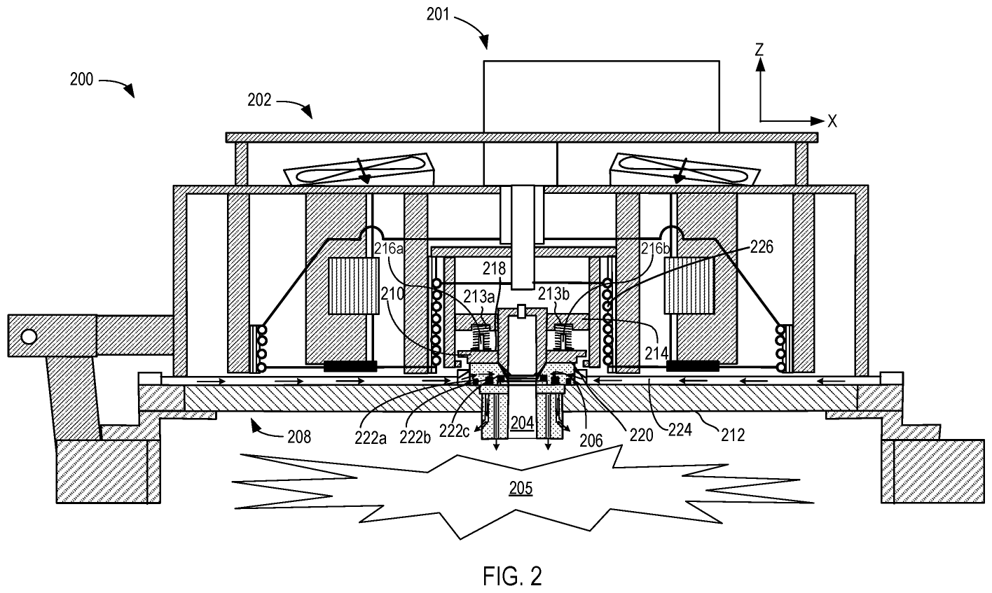

FIG. 2 shows a schematic cross-sectional partial view 200 of an example plasma processing chamber. Similar to the plasma processing chamber 100 of FIG. 1, the plasma processing chamber of FIG. 2 includes a chamber lid 208 arranged with respect to the chamber body to enclose a processing region. The partial view 200 includes an inductively coupled plasma (“ICP”) source 201, a gas distribution nozzle 204, a gas hub 206, and a chamber lid 208. The chamber lid 208 incorporates a gas delivery nozzle 204 within a central region of the chamber lid 208. During operation of the processing chamber, a plasma can be generated within the processing region as an aspect of a semiconductor plasma-based process.

The chamber lid 208 includes a lid portion 212. The lid portion 212 is substantially planar along a plane oriented on the x axis, where the lid portion 212 can be a substantially uniform thickness along the z axis across a dimension along the x axis of the lid portion and not including features that are less than a threshold dimension. The lid portion 212 includes an aperture through the orthogonal dimension of the lid portion, i.e., between a first and second surface of the lid portion. The lid portion 212 is formed from a single piece of dielectric material, e.g., a ceramic material such as Alumina or Yttria, quartz, or other suitable dielectric material. The lid portion 212 can be substantially disk shaped along a plane oriented on the x axis. A portion of the lid portion 212 is configured to be in contact with the chamber body to enclose the chamber. In this specification, a “top” of the lid portion refers to a side of the lid portion facing the gas hub. The shape and diameter can be configured according to the particular plasma processing chamber design.

The lid portion 212 has a specified thickness that can be determined based on various design parameters including material, strength needed, and overall system design. For example, the plasma processing chamber can operate in a vacuum and under high heat resulting from the plasma formation. The lid thickness may be partially based on the structural needs to satisfy operational parameters of maintaining a vacuum seal and avoiding heat or expansion damage. The chamber lid 208 can include a lip portion for seating the lid on one or more sidewall edges on the opening of the plasma processing chamber.

The chamber lid 208 can include a gas distribution nozzle 204, e.g., also referred to herein as “gas nozzle.” The gas distribution nozzle 204 is accommodated by the aperture formed in the lid portion 212, in other words, the gas distribution nozzle 204 is disposed within the aperture such that a portion of the gas distribution nozzle 204 is arranged within the lid portion 212 of the chamber lid 208.

The chamber lid 208 includes a gas hub 206 arranged on a first surface of the lid portion 212 and aligned with the gas distribution nozzle 204. The gas hub 206 receives etch gases from one or more gas lines, e.g., gas line 224, each providing one or more process gases from the gas panel. The gas hub 206 can have one or more plenums formed within to separate etch gases to be provided to different gas flow paths of the gas delivery nozzle 204.

The chamber lid 208 includes at least one seal, e.g., seal 222a, 222b, 222c, arranged between the gas hub 206 and the surface of the lid portion 212 and/or the gas distribution nozzle 204. For example, the chamber lid can include at least two, at least three, at least four, or more seals arranged between the gas hub and the surface of the lid portion and/or the gas nozzle. The gas hub, gas nozzle, and/or the lid portion can include grooves to accommodate at least a portion of the at least one seal, e.g., to prevent slippage or movement of the seal. The at least one seal can be, for example, an O-ring. The seal can be made of a plastic material selected based on a compatibility with the plasma-based processes, e.g., to have corrosion resistance and high-temperature compatibility. For example, the seals can be made of plastic, e.g., Chemraz® XPE.

In some implementations, the at least one seal is arranged between a surface of the gas hub 206 and a surface of the lid portion 212. Additionally, or alternatively, at least one seal can be arranged between the gas distribution nozzle 204 and the gas hub 206. As depicted in FIG. 2, the system includes three seals 222a, 222b, and 222c where two seals are located between the gas nozzle and the gas hub and one seal is arranged between the gas hub and the lid portion of the chamber lid.

The plasma processing chamber includes a source assembly 202 including a plasma source, e.g., ICP source 201, configured to direct RF energy into the chamber body to generate a plasma 205 within the processing volume (not shown). The ICP source 201 includes one or more inductor coils 226 coupled to a power supply configured to power the one or more inductor coils. The inductor coils 226 inductively couple energy, such as RF energy, through the gas hub 206 and chamber lid 208 to maintain a plasma 205 formed from the etch gases distributed within a plasma processing chamber. The ICP source 201 is oriented so that the inductively coupled energy causes charged particles of the etch gas plasma to flow toward a substrate held in the plasma processing chamber.

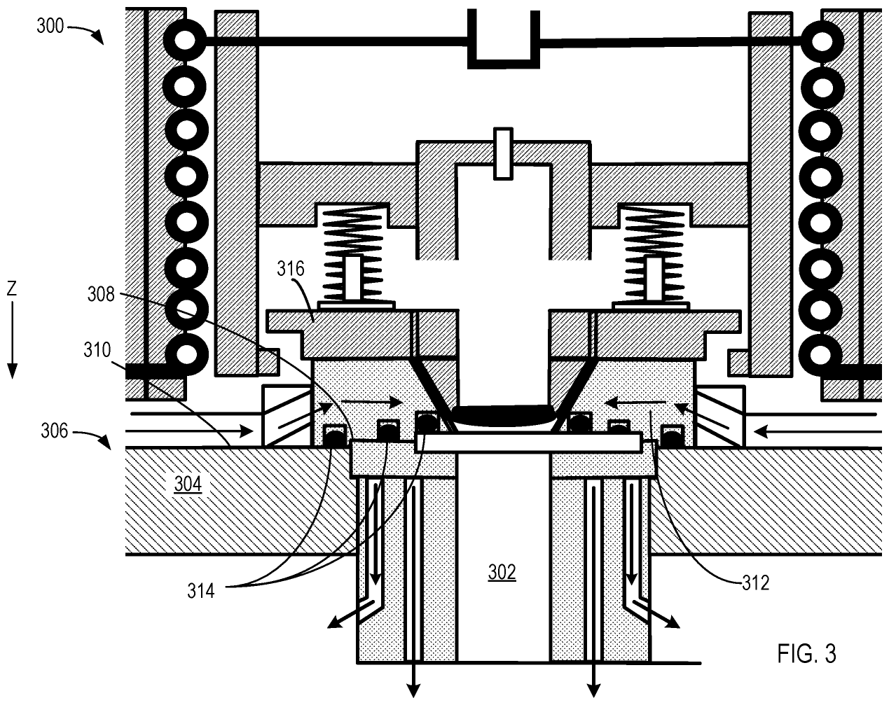

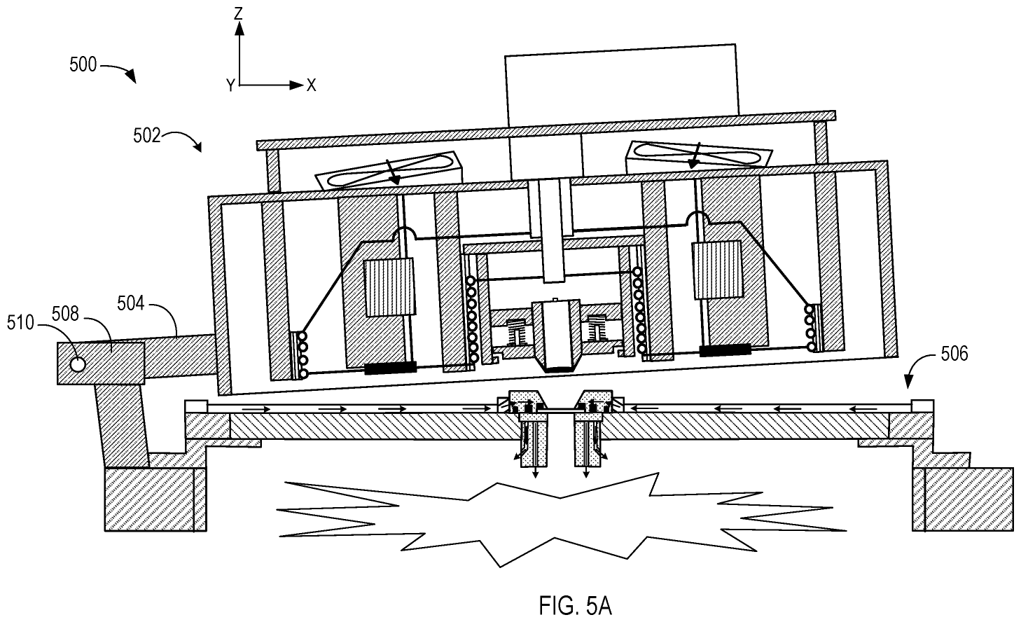

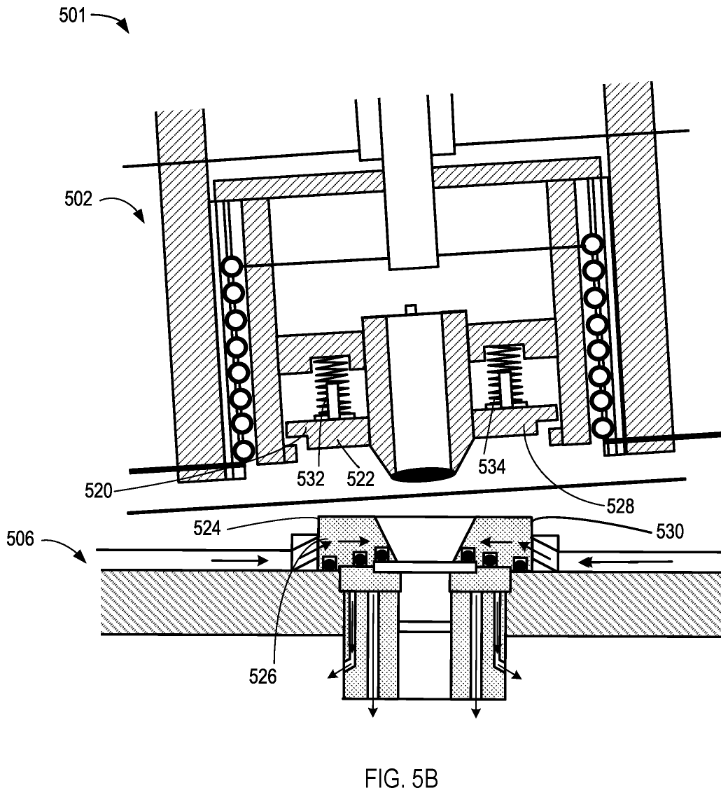

As depicted in FIGS. 5A and 5B, the source assembly 502 includes an adjustable support frame 504 that can be adjusted to position the source assembly with respect to the chamber lid 506. The adjustable positions can include at least a first, open position and a second, closed position with respect to the chamber lid. The adjustable support frame 504 can include a hinge portion 508, where the hinge portion 508 can adjust a position of the source assembly with respect to the chamber lid 506 from the first, open position, e.g., as depicted in FIGS. 5A and 5B, to the second, closed position, e.g., as depicted in FIG. 3.

Referring back to FIG. 2, the source assembly 202 includes a plate 210, e.g., also referred to herein as a “compression plate,” “spring-loaded plate,” or “clamp plate,” affixed to the source assembly. The plate 210 is moveable along an orthogonal z direction with respect to the source assembly 202 via a set of springs, e.g., springs 213a, 213b, that are affixed on one end to the plate 210 and on a second end to a fixture 214 of the source assembly 202, e.g., an integrated end point (IEP) of the source assembly. The set of springs are oriented orthogonally along the z-axis with respect to the plane of the plate 210, where each of the springs, e.g., springs 213a, 213b, can be aligned using a respective guide rod, e.g., guide rods 216a, 216b, affixed to the surface 218 of the plate 210.

In some implementations, the plate 210 is arranged with respect to the source assembly 202 to contact the gas hub 206 with a surface of the plate 210 opposite the surface to which the set of springs are affixed when the source assembly is in the second, closed position, such that the set of springs apply a compressive force orthogonally along the length of the set of the springs to compress the at least one seal, e.g., seal 222a, 222b, 222c, located between the first end of the gas hub 206 and the surface of the lid portion.

The springs of the set of springs are compression type springs. A length of the springs is selected in part on an amount of compressive force for each spring on the plate 210 and a number of springs in the set of springs. For example, a length can be between about 0.5″ and 1.5″. A material of the spring is selected in part based on the environment to which the spring is exposed. In the case of the source assembly, the springs are exposed to RF electromagnetic field during operation of the system, so the material of the springs must have nonmagnetic properties. The springs can be composed of a material selected based nonmagnetic properties. For example, the springs can be composed of brass or a plastic, e.g., polyether ether ketone (PEEK).

In some implementations, a number of springs of the set of springs is selected to provide an even compressive force by the springs on the plate along an orthogonal direction. For example, the set of springs can include at least three springs spaced evenly, i.e., equidistant, on the plate. In another example, the set of springs includes at least four springs. In another example, the set of springs includes five or more springs.

FIG. 3 shows a schematic cross-sectional partial view 300 of an example plasma processing chamber. As depicted, gas distribution nozzle 302 located within the aperture of the lid portion 304 of the chamber lid 306 includes a raised lip 308 above the surface 310 of the lid portion 304, where the raised lip 308 assists with alignment and retention of a gas hub 312 with respect to the lid portion 304 and gas distribution nozzle 302. Seals 314 are located between the gas hub 312 and the lid portion 304 as well as between the gas hub 312 and the gas distribution nozzle 302, where the gas hub 312 includes grooved portions to accommodate and retain the seals in place.

As depicted in FIG. 3, a portion of a plate 316 of the source assembly contacts an end of the gas hub 312, e.g., in a closed position. In the closed position, the spring-loaded plate 316 applies a uniform compressive force on the gas hub 312 along the z axis which in turn applies a compressive force to compress the seals 314 by at threshold amount. For example, the compressive force of the gas hub 312 onto the seals 314 can compress (i.e., deform) the seals by at least 15% when the spring-loaded plate 316 is in the closed position and contacting the gas hub 312. As described with reference to FIG. 2, the set of springs can include, for example, at least four springs arranged with respect to the plate to generate a uniform compression of the seals when the source assembly is in the closed position.

In some implementations, the compressive force of the gas hub onto the seals is at least, for example, at least 40 to 60 pounds (lbs) of force. A force exerted by each spring of the set of springs can depend in part on the number of springs in the set of springs. For example, in the instance where the set of springs includes 4 springs, each spring may be selected to exert at least 10 lbs of force.

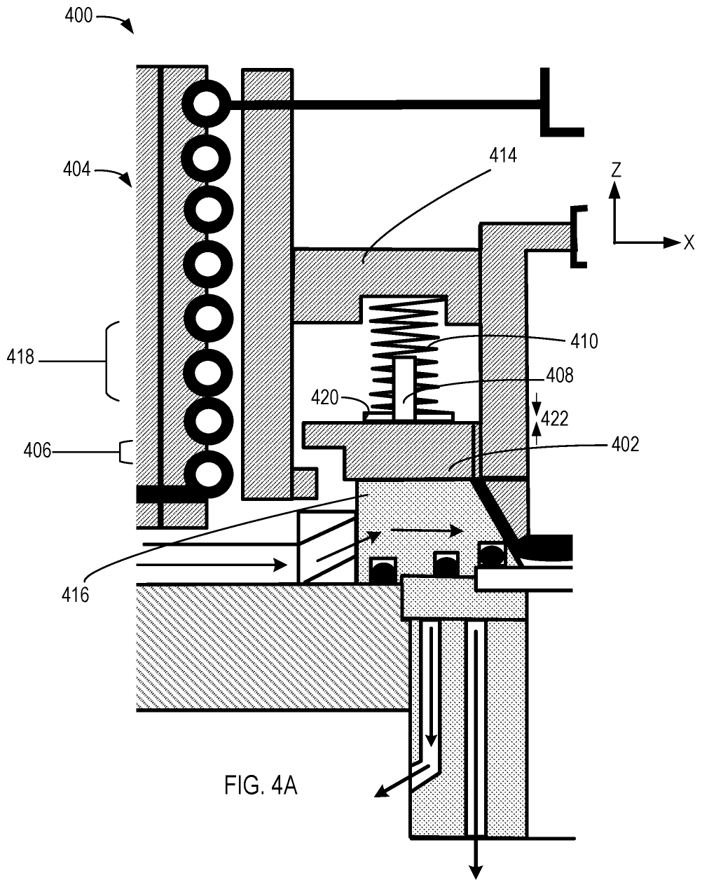

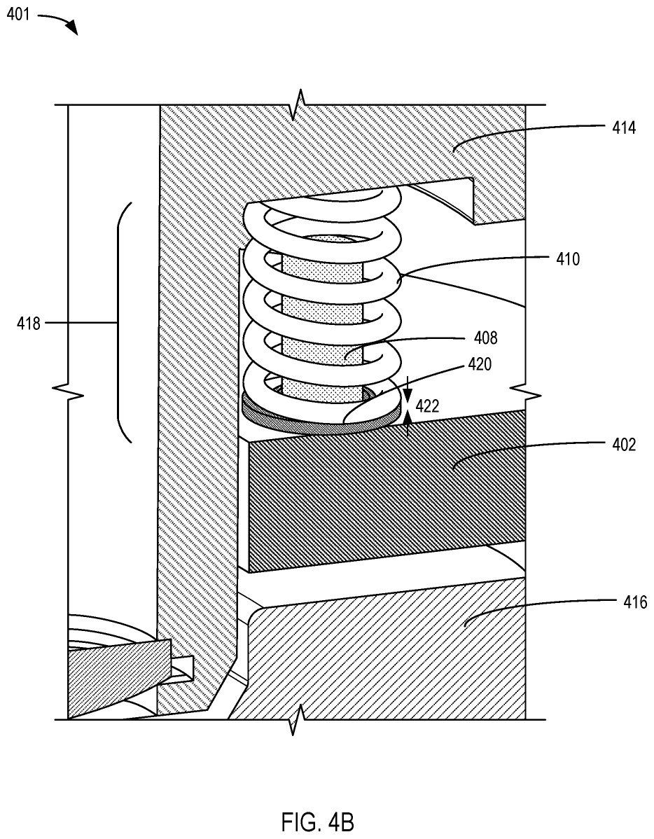

FIGS. 4A and 4B show various schematic cross-sectional partial views 400, 401 of example plasma processing chambers. The spring-loaded plate 402 is affixed to the source assembly 404 and moveable along a z-axis and orthogonal with respect to the source assembly along a stroke 406. Guide rods, e.g., guide rod 408, can be affixed to the plate 402 where each spring, e.g., spring 410, is concentrically located about a respective guide rod. The guide rods can be utilized to prevent substantial buckling of the springs as the plate contacts and applies force on the gas hub. Guide rods can be formed from a plastic material having a composition compatible with the plasma-based process, e.g., PEEK. A diameter of each guide rod can be selected such that the corresponding spring moves freely about the guide rod.

A length of the stroke 406 between the plate 402 and a holding fixture 414 of the source assembly 404 can be such that the gap is nearly zero when the source assembly is in a first, open position and the spring-loaded plate is not contacting a gas hub 416. Stroke 406 can be selected such that the distance between the plate 402 and the holding fixture 414 along the stroke can be a second non-zero value equal to the travel length of the stroke 406 when the source assembly is in the second, closed position and the spring-loaded plate is contacting the gas hub 416 and applying a compressive force along the z-axis on the gas hub 416, e.g., as depicted in FIG. 4. For example, a stroke length of the spring-loaded plate can be at least about 0.15″, 0.16″, 0.17″, 0.18″, 0.2″, 0.22″ or more.

A dimension of a spacing 418 between the holding fixture 414 and the spring-loaded plate 402 can be selected to accommodate a spring 410 having a minimum length to provide the target force of the spring-loaded plate on the gas hub to compress the seals. For example, in the case where the set of springs includes 4 springs, the dimension of the spacing can be at least about 0.5″, 0.75″, 0.8″, 0.825″ to accommodate a spring providing at least 10 lbs of force. A dimension of the spacing can additionally depend on a material the spring, where a first material of spring providing a greater force per length may result in a smaller dimension of the spacing than a second material of spring providing a lesser force per length.

In some implementations, at least one spacer 420 is located between a first end of at least one spring 410 of the set of springs and the first surface of the plate 402. The spacer 420 can be used to increase a compressive force applied by the spring 410 on the plate 402. A thickness 422 along the z-axis of the spacer can be selected in part on the increase in compression force needed for the spring. For example, a thickness of the washer can be selected to incrementally increase the compression force of the spring by about e.g., 1 lb, 1.5 lb, 2 lb, 2.5 lb, 3 lb, etc., per spacer added to the spring. When adding a washer to each of the set of springs, a total increase in the compression can be calculated linearly by adding the force per spacer by a number of springs implementing the spacer.

In some implementations, a spacer 420 is added to each spring of the set of springs to increase an overall compression force. In some implementations, a spacer can be added to one or more of the springs, e.g., to locally compensate for uneven force being applied by each of the set of springs.

In some implementations, spacers can be added to the set of springs to achieve a threshold vacuum integrity, i.e., a threshold vacuum level and/or vacuum stability, within the processing chamber.

FIGS. 5A and 5B show schematic cross-sectional partial views 500, 501 of an example plasma processing chamber. The source assembly 502 includes a moveable frame 504, e.g., also referred to as “an adjustable support frame,” to position the source assembly 502 with respect to the chamber lid 506, where the moveable frame 504 includes a includes a hinge 508 to position the source assembly at a first angle with respect to the plane along the x axis of the chamber lid 506. For example, the hinge 508 can move about a pivot 510 along the y axis by about 1 degree from an open position, e.g., as shown in FIG. 5A, to a closed position, e.g., as shown in FIG. 3.

In some implementations, the moveable frame 504 of the source assembly can freely move between an open and a closed position while the interior of the processing chamber is nominally as a same pressure as the exterior, e.g., at atmosphere. When the source assembly is located in the closed position, a vacuum can be established within the pressure chamber, e.g., using one or more pumps in fluidic contact with the pressure chamber. Once a threshold vacuum is established in the pressure chamber, the moveable frame is fixed in place by the pressure differential forming a vacuum seal.

Referring now to FIG. 5B, in some implementations, as the source assembly is moved from the open position to the closed position, a surface the spring-loaded plate contacts the gas hub, where a first portion 520 of the plate 522 can contact the first end 524 of the gas hub 526 before a second portion 528 of the plate 522 contacts a second end 530 gas hub 526. As such, one or more of the springs, e.g., spring 532, of the set of springs located closer to the hinge of the source assembly can be partially or fully compressed before one or more springs, e.g., spring 534, of the set of springs located further from the hinge of the source assembly is partially or fully compressed.

In some implementations, when the source assembly is in the closed position, each of the springs of the set of springs is nominally compressed a same amount, as the plate makes even contact with the first end of the gas hub, e.g., as depicted in FIG. 3.

As described with reference to FIG. 3, the gas nozzle includes a raised portion to retain the gas hub in place and to assist in guiding the alignment of the source assembly with respect to the chamber lid during the closing of the gap between the source assembly and the chamber lid.

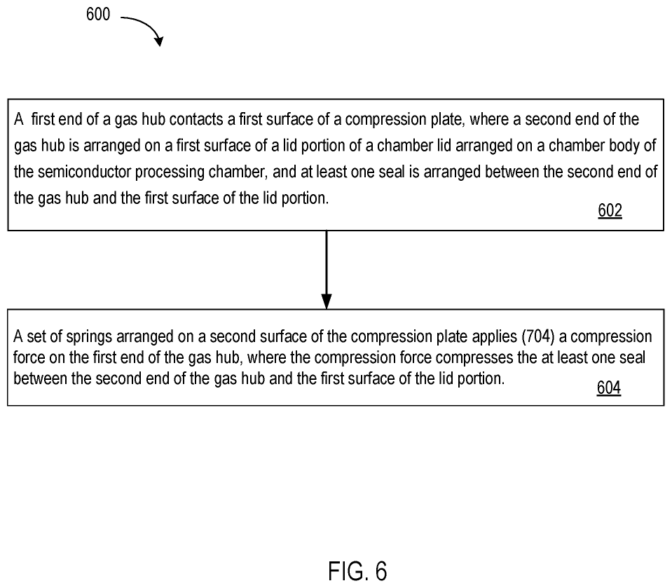

FIG. 6 is a flow diagram of an example of a process 600 of a semiconductor processing chamber. A first end of a gas hub contacts (602) a first surface of a compression plate, where a second end of the gas hub is arranged on a first surface of a lid portion of a chamber lid arranged on a chamber body of the semiconductor processing chamber, and at least one seal is arranged between the second end of the gas hub and the first surface of the lid portion. For example, as described with reference to FIG. 3, a spring-loaded plate 316 contacts a gas hub 312 and the gas hub 312 is arranged on a surface of a lid portion 304 of a chamber lid 306. As depicted in FIG. 1, the chamber lid 110 is arranged with respect to a chamber body 105 of a semiconductor processing chamber 100.

A set of springs arranged on a second surface of the compression plate applies (604) a compression force on the first end of the gas hub, where the compression force compresses the at least one seal between the second end of the gas hub and the first surface of the lid portion. Applying the compression force includes compressing a respective length of each spring of the set of springs between the compression plate and a fixture of the source assembly of the processing chamber. For example, the set of springs, e.g., springs 213a, 213b, are arranged between a plate 210 and a fixture 214 of the source assembly 202, where the spring-loaded plate 210 applies a compression force on a first end 220 of a gas hub 206, which in turn compresses a second end of the gas hub 206 and the lid portion 212 of the chamber lid 208. The compression between the gas hub 206 and the lid portion 212 applies a compressive force to the seals, e.g., seals 222a, 222b, 222c, to deform the seals and create a seal between the gas hub 206 and the lid portion 212 and gas nozzle 204.

In some implementations, the process further includes establishing, by a pump in fluid communication with the chamber body, e.g., via pumping port 145, a vacuum within a processing region, e.g., chamber volume 101, enclosed by the chamber body and the chamber lid. For example, establishing the vacuum within the processing region can be a vacuum level of at least 5 millitorr.

In some implementations, compressing the at least one seal, e.g., at least one O-ring, between the second end of the gas hub and the first surface of the lid portion includes compressing the at least one seal by at least 15% of a dimension of the seal along a direction of the applied compression force. For example, seals 314 between gas hub 312 and lid portion 304 and/or gas distribution nozzle 302. The compression force can be applying at least 40 lbs of compressive force on the at least one seal.

In some implementations, compressing the at least one seal includes applying a substantially uniform compression force on the at least one seal by the set of springs when the first end of the gas hub is fully contacted by the first surface of the compression plate. A number of springs of the set of springs can be selected to provide the substantially uniform compression force on the at least one seal, e.g., on the three O-rings, of the sealing mechanism.

In some implementations, applying the compression force includes, during a movement of the source assembly from an open position to a closed position, applying a compressive force by a first spring of the set of springs prior to applying a compressive force by a second spring of the set of springs at an intermediate contact position of the first surface of the compression plate on the first end of the gas hub.

In some implementations, the first end of the gas hub contacts the first surface of the compression plate by adjusting a position of a source assembly including the compression plate of the processing chamber from a first open, position to a second, closed position with respect to a fixed position of the chamber lid, e.g., by configuring the adjustable support frame including a hinge of the source assembly.

In some implementations, the compression force is applied to two or more seals between the second end of the gas hub and (A) the first surface of the lid portion and/or (B) a nozzle disposed within an aperture of the lid portion.

Aspects of the subject matter and the actions and operations described in this specification, for example, computing devices such as controller 165 and processes performed by controller 165 such as controlling of the gas panel and distribution of process gases to a plasma processing chamber, can be implemented in digital electronic circuitry, in tangibly-embodied computer software or firmware, in computer hardware, including the structures disclosed in this specification and their structural equivalents, or in combinations of one or more of them.

The subject matter and the actions and operations described in this specification can be implemented as or in one or more computer programs, e.g., one or more modules of computer program instructions, encoded on a computer program carrier, for execution by, or to control the operation of, data processing apparatus. The carrier can be a tangible non-transitory computer storage medium. Alternatively, or in addition, the carrier can be an artificially-generated propagated signal, e.g., a machine-generated electrical, optical, or electromagnetic signal, which is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application-specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages; and it can be deployed in any form, including as a stand-alone program, e.g., as an app, or as a module, component, engine, subroutine, or other unit suitable for executing in a computing environment, which environment can include one or more computers interconnected by a data communication network in one or more locations.

A computer program can, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or both, and any other kind of central processing unit. Generally, a central processing unit will receive instructions and data from a read-only memory or a random-access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. The mass storage devices can be, for example, magnetic, magneto-optical, or optical disks, or solid-state drives. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. A system for semiconductor processing, the system comprising:
a chamber body comprising a plurality of walls for enclosing a processing region;
a first substrate support within the chamber body and configured to retain a substrate in the processing region of the chamber body;
a chamber lid arranged with respect to the plurality of walls of the chamber body to enclose the processing region and comprising:
a lid portion comprising an aperture from a first surface of the lid portion to a second surface of the lid portion;
a gas distribution nozzle disposed within the aperture of the lid portion; and
a gas hub arranged on the first surface of the lid portion;
at least one seal arranged between a first end of the gas hub and the first surface of the lid portion; and
a source assembly comprising:
a plasma source configured to direct RF energy into the chamber body;
an adjustable support frame configurable to position the source assembly from a first, open position to a second, closed position with respect to the chamber lid;
a plate affixed to the source assembly; and
a set of springs affixed to a first surface of the plate and oriented orthogonally with respect to a plane of the plate,
wherein the plate is arranged with respect to the source assembly to contact a second end of the gas hub with a second surface of the plate when the source assembly is in a second, closed position, such that the set of springs apply a compressive force to compress the at least one seal located between the first end of the gas hub and the first surface of the lid portion.

2. The system of claim 1, wherein the set of springs apply the compressive force to compress the at least one seal by at least 15% when the source assembly is in the second, closed position.

3. The system of claim 1, wherein the set of springs comprises at least four springs arranged with respect to the plate to generate a uniform compression of the at least one seal when the source assembly is in the second, closed position.

4. The system of claim 1, further comprising at least one seal located between the first end of the gas hub and the gas distribution nozzle,
wherein the set of springs apply the compressive force to compress the at least one seal located between the first end of the gas hub and the gas distribution nozzle when the source assembly is in the second, closed position.

5. The system of claim 1, wherein the plate further comprises a set of guide rods, each guide rod corresponding to a respective spring of the set of the springs, and
wherein each of the set of springs is aligned along a respective guide rod of the set of guide rods.

6. The system of claim 1, wherein the at least one seal comprises an O-ring, and
wherein the at least 15% compression of the O-ring comprises at least 40 pounds of compressive force applied to the O-ring.

7. The system of claim 1, wherein the set of springs comprise brass.

8. The system of claim 1, further comprising:
at least one spacer located between a first end of at least one spring of the set of springs and the first surface of the plate, wherein the at least one spacer increases a compressive force applied by the at least one spring on the plate.

9. A method for spring-loaded sealing of a semiconductor processing chamber comprising:
contacting a first end of a gas hub with a first surface of a compression plate, wherein a second end of the gas hub is arranged on a first surface of a lid portion of a chamber lid arranged on a chamber body of the semiconductor processing chamber, wherein at least one seal is arranged between the second end of the gas hub and the first surface of the lid portion;
applying, by a set of springs arranged on a second surface of the compression plate, a compression force on the first end of the gas hub by the compression plate, the compression force compressing the at least one seal between the second end of the gas hub and the first surface of the lid portion.

10. The method of claim 9, wherein compressing the at least one seal between the second end of the gas hub and the first surface of the lid portion comprises compressing the at least one seal by at least 15% of a dimension of the seal along a direction of the applied compression force.

11. The method of claim 10, wherein compressing the at least one seal comprises applying at least 40 pounds of compressive force on the at least one seal.

12. The method of claim 9, wherein applying the compression force comprises applying a substantially uniform compression force on the at least one seal by the set of springs when the first end of the gas hub is fully contacted by the first surface of the compression plate.

13. The method of claim 12, wherein applying the compression force comprises applying a compressive force by a first spring of the set of springs prior to applying a compressive force by a second spring of the set of springs at an intermediate contact position of the first surface of the compression plate on the first end of the gas hub.

14. The method of claim 9, wherein contacting the first end of the gas hub with the first surface of the compression plate comprises
adjusting a position of a source assembly including the compression plate of the processing chamber from a first open, position to a second, closed position with respect to the chamber lid.

15. The method of claim 14, wherein adjusting the position of the source assembly includes configuring an adjustable support frame of the source assembly to adjust a position the source assembly from the first, open position to the second, closed position.

16. The method of claim 14, wherein applying the compression force comprises applying a compressive force by the set of springs on two or more seals between the second end of the gas hub and (A) the first surface of the lid portion and/or (B) a nozzle disposed within an aperture of the lid portion.

17. The method of claim 14, wherein applying the compression force comprises compressing a respective length of each spring of the set of springs between the compression plate a fixture of a source assembly of the processing chamber.

18. The method of claim 9, further comprising:
establishing, by a pump in fluid communication with the chamber body, a vacuum within a processing region enclosed by the chamber body and the chamber lid.

19. The method of claim 18, wherein establishing the vacuum within the processing region comprises a vacuum level of at least 5 millitorr.

20. A spring-loaded sealing mechanism for a chamber lid of a semiconductor processing chamber comprising:
a compression plate affixed to a source assembly of the processing chamber; and
a set of springs comprising:
first ends of each of the set of springs affixed to a first surface of the compression plate;
respective lengths of each of the set of springs oriented orthogonally with respect to a plane of the compression plate; and
second ends of each of the set of springs contacting a fixture of the source assembly;
wherein the compression plate is arranged with respect to the source assembly such that, when the source assembly is in a closed position, the compression plate applies a compressive force on a gas hub of the chamber lid to compress a dimension of at least one seal between the gas hub and the chamber lid by at least 15%.
